(19) United States
(12) Patent Application Publication
(10) Pub. No.: US 2025/0279568 A1
(43) Pub. Date: Sep. 4, 2025

(54) SUPERCONDUCTING QUANTUM CHIP AND PARAMETER DETERMINATION METHOD THEREFOR

(71) Applicant: YANGTZE DELTA INDUSTRIAL INNOVATION CENTER OF QUANTUM SCIENCE AND TECHNOLOGY, Suzhou (CN)

(72) Inventors: Baojun LU, Suzhou (CN); Hui YANG, Suzhou (CN); Huide ZHOU, Suzhou (CN); Bo FAN, Suzhou (CN); Tian LUAN, Suzhou (CN)

(21) Appl. No.: 18/796,350

(22) Filed: Aug. 7, 2024

Related U.S. Application Data
(63) Continuation of application No. PCT/CN2022/135140, filed on Nov. 29, 2022.

(30) Foreign Application Priority Data
Aug. 3, 2022 (CN) 202210928530.7

(51) Int. Cl. H01P 7/08; G01R 27/02

(52) U.S. Cl. CPC H01P 7/086; G01R 27/02

(57) ABSTRACT

The present disclosure discloses a superconducting quantum chip and parameter determination method therefor, and relates to the field of quantum chips. The superconducting quantum chip includes a chip substrate and a quantum module formed on the chip substrate. The quantum module includes a bit capacitor unit, a readout line unit, and a Josephson junction unit. The quantum module further includes a Coplanar Waveguide-Step Impedance Resonator (CPW-SIR) unit. In the superconducting quantum chip disclosed by the present application, functions of a resonator are realized by virtue of the CPW-SIR unit. Thanks to physical properties of the CPW-SIR unit, in a same parallel resonance condition, compared with a Uniformity Impedance Resonator (UIR), the electrical length of the SIR is obviously less

### CROSS-REFERENCE TO RELATED APPLICATIONS

The present application is a continuation of International Application No. PCT/CN2022/135140, with an international filing date of Nov. 29, 2022, which is based upon and claims priority to Chinese Patent Application No. 202210928530.7, filed on Aug. 3, 2022, the entire contents of all of which are incorporated herein by reference.

### TECHNICAL FIELD

The present disclosure relates to the field of quantum chips and particularly relates to a superconducting quantum chip and parameter determination method therefor.

### BACKGROUND

A quantum chip is a core component of a quantum computer, mainly including a quantum chip of a superconducting system, a semiconductor quantum chip, a quantum dot chip, an ion trap, an NV (diamond) color center, and the like. At present, the quantum chip of the superconducting system is usually structured such that structures such as a quantum bit, a reading cavity, a resonator, a Josephson junction, a microwave line and a port are formed on a substrate.

The resonators in the conventional superconducting quantum chip all use coplanar waveguides in the form of uniform impedance, that is, the resonators are Coplanar Waveguide-Uniformity Impedance Resonators (CPW-UIR), and the length of the resonators is λ_{g}/4, where λ_{g} is a waveguide wavelength corresponding to a resonant frequency.

With improvement of the requirement on the computing power of a quantum computer, the requirement on the integration level of the quantum chip is increasingly high. To shorten the size of the conventional superconducting chip, the resonators are arranged in the form of a meander line. But this arrangement still occupies large space.

Therefore, to provide a solution to solve the above technical problem is still a problem demanding prompt solution by those skilled in the art at present.

### SUMMARY

In view of this, an object of the present disclosure is to provide a superconducting quantum chip and parameter determination method therefor, to shorten the size of the superconducting quantum chip. A specific solution is as follows:

A superconducting quantum chip includes a chip substrate and a quantum module formed on the chip substrate, where the quantum module includes a bit capacitor unit, a readout line unit a Josephson junction unit; and the quantum module further includes a Coplanar Waveguide-Step Impedance Resonator (CPW-SIR) unit.

Preferably, the CPW-SIR unit is specifically a Coplanar Waveguide-2-Step Step Impedance Resonator unit.

Preferably, the CPW-SIR unit is specifically a Coplanar Waveguide-3-Step Step Impedance Resonator unit.

Preferably, the bit capacitor unit is specifically a bit capacitor unit of a cross structure.

Preferably, the readout line unit is specifically a transmission line of a coplanar waveguide structure.

Preferably, the CPW-SIR unit is specifically a λ_{g}/4 type CPW-SIR unit, and λ_{g} is a waveguide wavelength corresponding to a resonant frequency of the CPW-SIR unit.

Correspondingly, the present application further discloses a parameter determination method of a superconducting quantum chip, applied to the superconducting quantum chip according to any one of the above, including:
determining characteristic impedance of a transmission line of each step of a Coplanar Waveguide-Step Impedance Resonator (CPW-SIR) unit according to a preset accuracy, and taking the characteristic impedance as a characteristic impedance parameter;
calculating characteristic impedance ratios among the characteristic impedances of all characteristic lines;
determining a curve relationship between an electrical length of the characteristic line and a total electrical length at the characteristic impedance ratio, and the total electrical length is specifically a sum of the electrical lengths of all the characteristic lines;
determining a minimum total electrical length interval of the total electrical length and an electrical length interval of the characteristic lines corresponding to the minimum total electrical length interval according to the curve relationship; and
determining the electrical length corresponding to the preset accuracy within the electrical length interval of the characteristic line of each step, so as to take the electrical length as an electrical length parameter of the transmission line of each step of the CPW-SIR unit.

Preferably, the CPW-SIR unit is the Coplanar Waveguide-2-Step Step Impedance Resonator unit;
the process of calculating characteristic impedance ratios among the characteristic impedances of all characteristic lines includes:
calculating a characteristic impedance ratio between the characteristic impedance of the characteristic line of a second step and the characteristic impedance of the characteristic line of a first step.

Preferably, the process of determining a curve relationship between an electrical length of the characteristic line and a total electrical length at the characteristic impedance ratio includes:
determining a curve relationship between the characteristic line of the first step and the total electrical length at the characteristic impedance ratio.

Preferably, the process of determining the electrical length corresponding to the preset accuracy within the electrical length interval of the characteristic line of each step includes:
determining the electrical length corresponding to the preset accuracy within the electrical length interval of the characteristic line of the first step and taking the electrical length as a first-step electrical length parameter of the characteristic line of the first step;
determining the total electrical length corresponding to the first-step electrical length parameter according to the curve relationship; and
determining a second-step electrical length parameter of the characteristic line of the second step according to the total electrical length and the first-step electrical length parameter.

The present application discloses a superconducting quantum chip, including a chip substrate and a quantum module formed on the chip substrate, where the quantum module includes a bit capacitor unit, a readout line unit a Josephson junction unit; and the quantum module further includes a Coplanar Waveguide-Step Impedance Resonator (CPW-SIR) unit. In the superconducting quantum chip disclosed by the present application, functions of a resonator are realized by virtue of the CPW-SIR unit. Thanks to physical properties of the CPW-SIR unit, in a same parallel resonance condition, compared with a Uniformity Impedance Resonator (UIR), the electrical length of the SIR is obviously less, so that the layout size of a single quantum bit is reduced, the size of the quantum chip with a specific quantity of bits is smaller, the degree of freedom of the quantum chip is higher, and the integration level of the quantum chip is improved.

### BRIEF DESCRIPTION OF THE DRAWINGS

In order to describe the embodiments of the present disclosure or the technical solution in the prior art more clearly, drawings needed to be used in the embodiment will be described briefly below. It is apparent that the drawings described below are embodiments of the present disclosure, and those skilled in the technical field further can obtain other drawings according to the drawings without making creative efforts.

FIG. 1 is a structural distribution diagram of a superconducting quantum chip in an embodiment of the present disclosure;

FIG. 2 is a structural distribution diagram of a Coplanar Waveguide-Uniformity Impedance Resonator (CPW-SIR) unit in the embodiment of the present disclosure;

FIG. 3 is a flowchart of steps of a parameter determination method of the superconducting quantum chip in the embodiment of the present disclosure;

FIG. 4 is a structural distribution diagram of a Coplanar Waveguide-2-Step Step Impedance Resonator in the embodiment of the present disclosure;

FIG. 5 is a relationship curve diagram between an electrical length θ1 and a normalized electrical length Ln in the embodiment of the present disclosure;

FIG. 6a and FIG. 6b are respectively structural distribution diagrams of the superconducting quantum chip and a conventional superconducting quantum chip in the embodiment of the present disclosure;

FIG. 7a and FIG. 7b are simulation result diagrams of a single-bit superconducting quantum chip in the embodiment of the present disclosure; and

FIG. 8a and FIG. 8b are simulation result diagrams of a conventional single-bit superconducting quantum chip.

### DESCRIPTION OF THE EMBODIMENTS

The technical solution in the embodiments of the present disclosure will be clearly and completely described below in combination with the drawings in the embodiments of the present disclosure. Apparently, the embodiments described are merely some rather than all of the embodiments of the present disclosure. On the basis of the embodiments in the present disclosure, all other embodiments obtained by those skilled in the technical field without creative efforts fall into the scope of protection of the present disclosure.

With improvement of the requirement on the computing power of a quantum computer, the requirement on the integration level of the quantum chip is increasingly high. To shorten the size of the conventional superconducting chip, the resonators are arranged in the form of a meander line. But this arrangement still occupies large space.

In the superconducting quantum chip disclosed by the present application, functions of the resonator are realized by virtue of the CPW-SIR unit. Thanks to physical properties of the CPW-SIR unit, in a same parallel resonance condition, compared with a Uniformity Impedance Resonator (UIR), the electrical length of the SIR is obviously less, so that the layout size of a single quantum bit is reduced, the size of the quantum chip with a specific bit number is smaller, the degree of freedom of the quantum chip is higher, and the integration level of the quantum chip is improved.

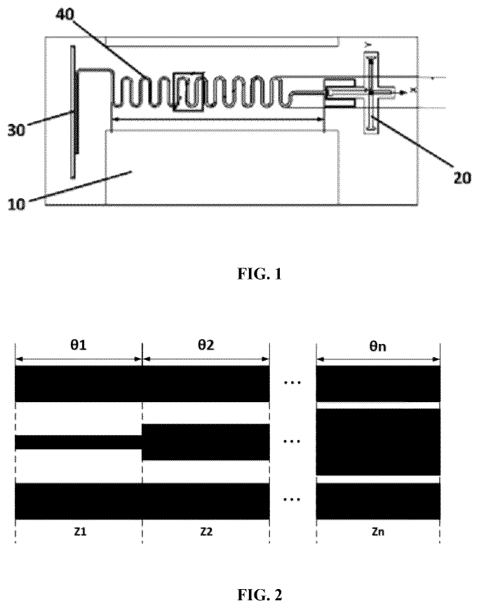

The embodiment of the present disclosure discloses a superconducting quantum chip, as shown in FIG. 1. FIG. 1 is a structural diagram of the superconducting quantum chip applied to a single-bit superconducting quantum chip. The superconducting quantum chip, includes a chip substrate 10 and a quantum module formed on the chip substrate 10. The quantum module includes a bit capacitor unit 20, a readout line unit 30, and a Josephson junction unit. The quantum module further includes a Coplanar Waveguide-Step Impedance Resonator (CPW-SIR) unit 40.

In some specific embodiments, the bit capacitor unit 20 formed on the chip substrate 10 is specifically a bit capacitor unit of a cross structure. Further, the readout line unit 30 formed on the chip substrate 10 is specifically a transmission line of a coplanar waveguide structure (CPW).

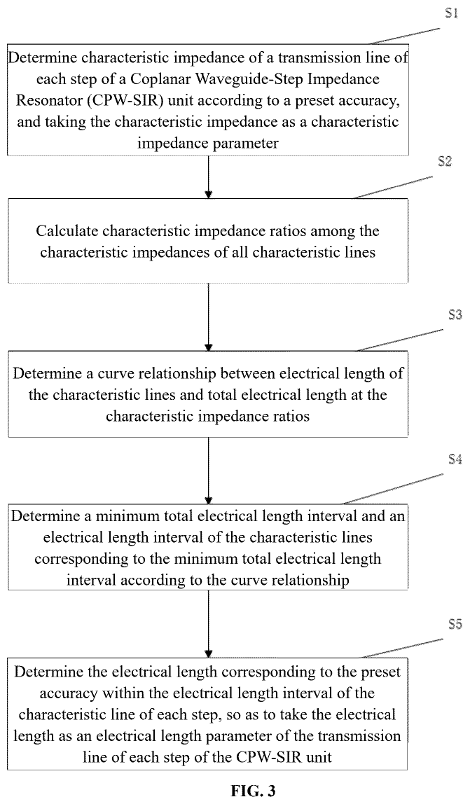

It can be understood that the CPW-SIR unit 40 mainly includes a Coplanar Waveguide-Step Impedance Resonator (CPW-SIR), which is a transverse electric and magnetic field mode or a quasi-transverse electric and magnetic field mode resonator formed by combining two or more CPW transmission lines with different characteristic impedance, where, as shown in FIG. 2, θ1, θ2 . . . θn are respectively the electrical lengths of the Coplanar Waveguide (CPW) transmission lines in different sections, and Z1, Z2 . . . Zn are respectively the characteristic impedance of the CPW transmission lines in different sections. With increase of the quantity of the CPW transmission lines, the physical sizes of the resonator are capable of being adjusted with changes of an electrical length relationship and a characteristic impedance relationship of the multiple CPW transmission lines within a certain range, further as a ground for a miniaturized design of the superconducting quantum chip in the embodiment.

In some specific embodiments, the CPW-SIR unit is specifically a λ_{g}/4 type CPW-SIR unit, λ_{g} being a waveguide wavelength corresponding to a resonant frequency of the CPW-SIR unit.

Further, in consideration of influences on a machining precision and a miniaturized effect of the resonant cavity unit, the CPW-SIR unit is specifically the coplanar waveguide-2-step step impedance resonator unit or the coplanar waveguide-3-step step impedance resonator unit.

According to the description in the embodiment, parameters of a specific superconducting quantum chip can be as follows: the chip substrate 10 is an Si silicon wafer, a dielectric constant εᵣ of the silicon wafer is equal to 11.9, and a thickness is 500 μm; a line width of the readout line unit 30 is 10 μm, and a slot width is 5 μm; the CPW-SIR unit is specifically the coplanar waveguide-2-step step impedance resonator unit, where for a first-step characteristic line, the characteristic specific superconducting quantum chip of the CPW transmission line of a Z1 section is about 74Ω, the line width w of a corresponding center line is equal to 2 μm, and the width s of the slot line is equal to 5 μm; for a second-step characteristic line, the characteristic impedance of the CPW transmission line of a Z2 section is about 38Ω, the line width w of a corresponding center line is equal to 8 μm, and the width s of the slot line is equal to 2 μm.

The present application discloses a superconducting quantum chip, including a chip substrate and a quantum module formed on the chip substrate, where the quantum module includes a bit capacitor unit, a readout line unit a Josephson junction unit; and the quantum module further includes a Coplanar Waveguide-Step Impedance Resonator (CPW-SIR) unit. In the superconducting quantum chip disclosed by the present application, functions of the resonator are realized by virtue of the CPW-SIR unit. Thanks to physical properties of the CPW-SIR unit, in a same parallel resonance condition, compared with a Uniformity Impedance Resonator (UIR), the electrical length of the SIR is obviously less, so that the layout size of a single quantum bit is reduced, the size of the quantum chip with a specific bit number is smaller, the degree of freedom of the quantum chip is higher, and the integration level of the quantum chip is improved.

Correspondingly, the present application further discloses a parameter determination method of a superconducting quantum chip, applied to the superconducting quantum chip according to any one of the above, as shown in FIG. 3, including:

S1: determining characteristic impedance of a transmission line of each step of a Coplanar Waveguide-Step Impedance Resonator (CPW-SIR) unit according to a preset accuracy, and taking the characteristic impedance as a characteristic impedance parameter;
where the preset accuracy is designed according to an actual machining capability or a design requirement; and the known CPW-SIR unit includes transmission lines of multiple steps to respectively determine the characteristic impedance of the transmission line of each step;

S2: calculating characteristic impedance ratios among the characteristic impedances of all characteristic lines;

S3: determining a curve relationship between an electrical length of the characteristic line and a total electrical length at the characteristic impedance ratio, and the total electrical length is specifically a sum of the electrical lengths of all the characteristic lines;

S4: determining a minimum total electrical length interval and an electrical length interval of the characteristic lines corresponding to the minimum total electrical length interval according to the curve relationship; and

S5: determining the electrical length corresponding to the preset accuracy within the electrical length interval of the characteristic line of each step, so as to take the electrical length as an electrical length parameter of the transmission line of each step of the CPW-SIR unit.

It can be understood that the CPW-SIR unit 40 mainly includes a Coplanar Waveguide-Step Impedance Resonator (CPW-SIR), which is a transverse electric and magnetic field mode or a quasi-transverse electric and magnetic field mode resonator formed by combining two or more CPW transmission lines with different characteristic impedance, as shown in FIG. 2, where θ1, θ2 . . . On are respectively the electrical lengths of the Coplanar Waveguide (CPW) transmission lines in different sections, and Z1, Z2 . . . Zn are respectively the characteristic impedance of the CPW transmission lines in different sections. With increase of the quantity of the CPW transmission lines, the physical sizes of the resonator are capable of being adjusted with changes of an electrical length relationship and a characteristic impedance relationship of the multiple CPW transmission lines within a certain range, further as a ground for a miniaturized design of the superconducting quantum chip in the embodiment.

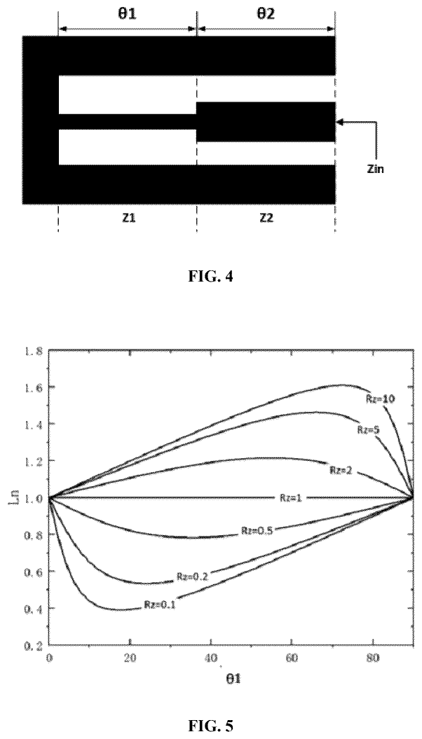

In some specific embodiments, the CPW-SIR unit is the coplanar waveguide-2-step step impedance resonator unit; by taking the coplanar waveguide-2-step step impedance resonator unit as an example, the structural diagram is shown in FIG. 4, neglecting noncontinuity of a nodal step and an edge capacitance of an open section. According to a theory of transmission lines, the input impedance Zin can be approximately represented as:

$$Zin = jZ 2 \times \frac{Z 1 \times tan θ1 + Z 2 \times tan θ2}{Z 2 - Z 1 \times tan θ1 \times tan θ2} ;$$

a parallel resonant condition thereof is as follows:

$$Z 2 - Z 1 \times tan θ1 \times tan θ2 = 0 ;$$

therefore:

$$tan θ1 \times tan θ2 = \frac{Z 2}{Z 1} = Rz ;$$

it can be seen that the resonant condition of the coplanar waveguide-2-step step impedance resonator unit is relevant not only to the electrical lengths θ1 and θ2, but also to the characteristic impedance ratio Rz. Compared with the structure of the CPW-UIR which is only dependent on the electrical length of the CPW transmission line, the coplanar waveguide-2-step step impedance resonator unit further has the parameter characteristic impedance ratio Rz to adjust the total electrical length of the resonator unit.

Further, the total length θtotal of the coplanar waveguide-2-step step impedance resonator unit is specifically as follows:

$$θ total = θ1 + θ2 = θ1 + arctan ( Rz / tan θ1 ; )$$

in this case, the electrical length of the CPW-UIR in the conventional superconducting quantum chip π/2, and after normalized processing of θtotal, the normalized electrical length Ln of the coplanar waveguide-2-step step impedance resonator unit is as follows:

$$Ln = θ total / \frac{π}{2} ;$$

further, for different characteristic impedance ratios Rz, the relationship curves of the electrical length θ1 and the normalized electrical length Ln are shown in FIG. 5. It can be seen that when Rz>1, the normalized electrical length Ln has a maximum value, and in this case, the electrical length of the CPW-UIR is less than the total electrical length θtotal of the coplanar waveguide-2-step step impedance resonator unit. On the contrary, when Rz<1, the normalized electrical length Ln has a minimum value, and the electrical length of the CPW-UIR is greater than the total length θtotal of the coplanar waveguide-2-step step impedance resonator unit. Therefore, the coplanar waveguide-2-step step impedance resonator unit with Rz<1 is selected. The total length θtotal can be shortened. The CPW-SIR units of other steps also have such characteristics, so that the theory is applied to the miniaturized design of the superconducting quantum chip. In consideration of a product accuracy and benefits, the coplanar waveguide-2-step step impedance resonator unit or the coplanar waveguide-3-step step impedance resonator unit is usually selected as the CPW-SIR unit.

In some specific embodiments, when the CWP-SIR unit is the coplanar waveguide-2-step step Impedance Resonator unit, the process of calculating the characteristic impedance ratio between the characteristic impedance of all the characteristic lines in S2 includes:
calculating a characteristic impedance ratio between the characteristic impedance of the characteristic line of a second step and the characteristic impedance of the characteristic line of a first step.

Further, the process of determining a curve relationship between electrical length of each of the characteristic lines and total electrical length of all the characteristic lines at the characteristic impedance ratios in S3 includes:
determining a curve relationship between the characteristic line of the first step and the total electrical length of all the characteristic lines at the characteristic impedance ratios.

Further, the process of determining the electrical length corresponding to the preset accuracy within the electrical length interval of the characteristic line of each step in S5 includes:
determining the electrical length corresponding to the preset accuracy within the electrical length interval of the characteristic line of the first step and taking the electrical length as a first-step electrical length parameter of the characteristic line of the first step;
determining the total electrical length corresponding to the first-step electrical length parameter according to the curve relationship; and
determining a second-step electrical length parameter of the characteristic line of the second step according to the total electrical length and the first-step electrical length parameter.

By taking a specific superconducting quantum chip as an example, the chip substrate 10 is an Si silicon wafer, a dielectric constant & of the silicon wafer is equal to 11.9, and a thickness is 500 μm; a line width of the readout line unit 30 is 10 μm, and a slot width is 5 μm; the CPW-SIR unit is specifically the coplanar waveguide-2-step step impedance resonator unit, and the process of calculating the coplanar waveguide-2-step step impedance resonator unit is as follows:
according to the preset accuracy, determining parameters of the characteristic impedance as follows: the characteristic impedance Z1 of the characteristic line of the first step is about 74Ω, and the characteristic impedance ZW of the characteristic line of the second step is about 38Ω;
calculating characteristic impedance ratios

$$Rz = \frac{Z 2}{Z 1} \approx 0.514$$

among the characteristic impedances of all characteristic lines;
determining a curve relationship between the characteristic line of the first step and the total electrical length of all the characteristic lines at the characteristic impedance ratios, and the curve relationship is approximate to a curve of Rz=0.5 in FIG. 5 and can serve as a reference; and

According to the curve relationship of Rz=0.514, determining the minimum total length interval and the electrical length interval of each of the characteristic lines corresponding thereto, where elements in the minimum total length interval include a minimum value of the curve relationship Ln. In consideration of a design requirement, the minimum value is not always selected directly, and a piece of data convenient to process is only selected from a result approximate to the minimum value. Therefore, the minimum total length interval can be a previous 1/n interval from the minimum value to the maximum value on the curve relationship Ln, n can be adjusted according to an actual design requirement, and for example, when n=3, the previous ⅓ interval with minimum Ln in the curve relationship is taken as the minimum total length interval, so that the electrical length interval of the corresponding characteristic line of the first step is further determined.

Further, an electrical length which is convenient to design or machine and satisfies the preset accuracy requirement is determined as the electrical length parameter of the characteristic line of the first step in the electrical length interval of the characteristic line of the first step. For example, the electrical length parameter θ1 of the characteristic line of the first step can be equal to 45°. According to the curve relationship, the corresponding total electrical length can be determined when the electrical length parameter θ1 of the characteristic line of the first step is equal to 45°. Then the electrical length parameter of the characteristic line of the second step can be then determined according to the total electrical length and the electrical length parameter θ1 of the characteristic line of the first step.

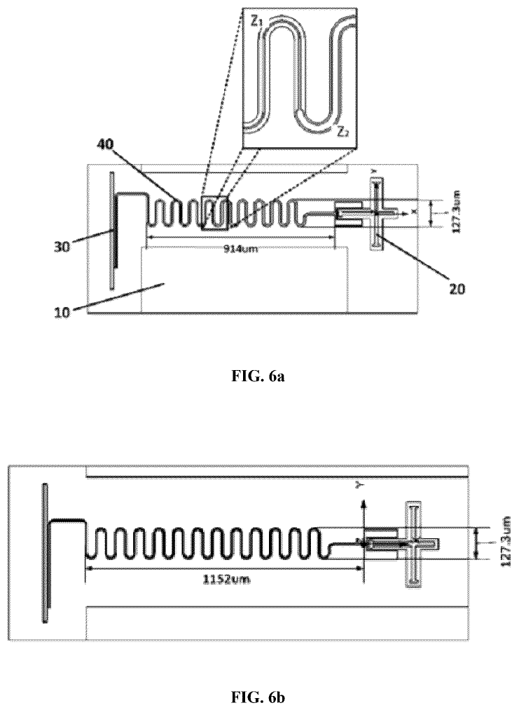

As shown in FIG. 6a and FIG. 6b, in this case, the total electrical length of all the characteristic lines in the CPW-SIR unit is about 3437.053 μm, and the layout area of the line meander portion is 914 μm×123.7 μm; in the same parameter resonant condition, the length of the resonator in the conventional single-bit superconducting quantum chip is about 4277.244 μm, and the layout area of the line meander portion is 1152 μm×123.7 μm.

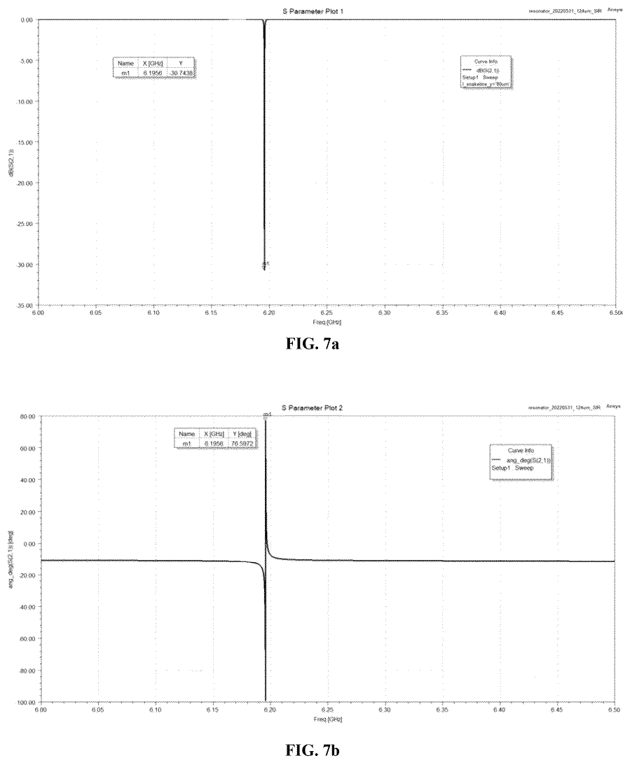

Specifically, in the simulation results of the conventional single-bit superconducting quantum chip shown in FIG. 7a and FIG. 7b, the working frequency of the resonator is 6.1956 GHz;

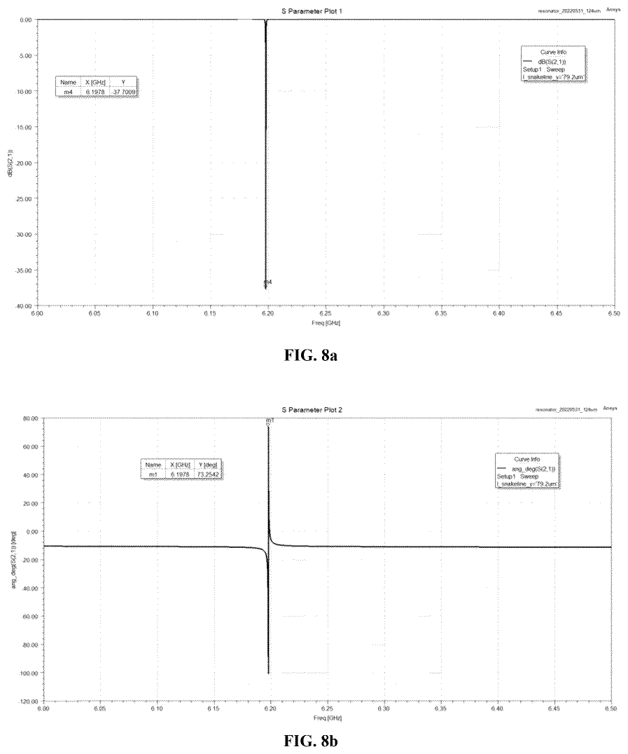

Specifically, in the simulation results of the conventional single-bit superconducting quantum chip shown in FIG. 8a and FIG. 8b, the working frequency of the resonator is 6.1978 GHz.

It can be seen that at close working frequencies of the superconducting quantum chip in the embodiment and the conventional superconducting quantum chip, the size of the resonator based on the coplanar waveguide-2-step step impedance resonator unit is shortened by about 19.6% compared with that of the conventional UIR.

It can be understood that the coplanar waveguide-2-step step impedance resonator unit is specifically described above. The parameter determination method of the coplanar waveguide-3-step step impedance resonator unit is similar to that of the coplanar waveguide-2-step step impedance resonator unit. With increase of the transmission lines, the characteristic impedance ratio is no longer a single variable. When the characteristic impedance ratio is calculated in S2, usually the characteristic impedance of a certain characteristic line is taken as a denominator and the characteristic impedance of other characteristic lines is taken as numerators to respectively calculate the corresponding plurality of characteristic impedance ratios.

In S3, the curve relationship with the electrical length of the characteristic line taking the characteristic impedance as the denominator as a self-variable and the total length of all the characteristic lines as a dependent variable at the plurality of characteristic impedance ratios of the group is determined; in the curve relationship subsequently, the method of determining the minimum total length interval, the electrical length interval of the self-variable, and the specific electrical length parameter is similar to that above, which is not described repeatedly herein.

In the superconducting quantum chip disclosed by the present application, functions of the resonator are realized by virtue of the CPW-SIR unit. Thanks to physical properties of the CPW-SIR unit, in a same parallel resonance condition, compared with a Uniformity Impedance Resonator (UIR), the electrical length of the SIR is obviously less, so that the layout size of a single quantum bit is reduced, the size of the quantum chip with a specific bit number is smaller, the degree of freedom of the quantum chip is higher, and the integration level of the quantum chip is improved.

Finally, it is to be further noted that the relationship terms herein such as first and second are merely used for differentiating one body or operation from another body or operation rather than requiring or hinting any actual relationship or sequence among the bodies or operations. In addition, the terms “include”, “contain”, or any other variations thereof are intended to cover non-exclusive inclusions, such that a process, a method, an article, or a device including a series of elements not only includes those elements, but also includes other elements that are not explicitly listed, or further includes inherent elements of the process, the method, the article, or the apparatus. Under a circumstance of no more limitations, for the elements defined by the term “include one”, a condition that there are additional same elements in the process, method, article or apparatus including the elements is not excluded.

A superconducting quantum chip and a parameter determination method of the superconducting quantum chip provided by the present disclosure are introduced in detail above. Particular examples are used herein to explain the principle and embodiments of the patent, and the above description of the embodiments is only used to help understanding the methods and core concept of the present disclosure. Moreover, alternations will be made by those of ordinary skill in the art on the specific embodiments and application range in accordance with the thought of the present disclosure. In conclusion, the content of the description shall not be construed as limitation to the present disclosure.

What is claimed is:

1. A superconducting quantum chip, comprising a chip substrate and a quantum module formed on the chip substrate, wherein the quantum module comprises a bit capacitor unit, a readout line unit, and a Josephson junction unit; and the quantum module further comprises a Coplanar Waveguide-Step Impedance Resonator (CPW-SIR) unit.

2. The superconducting quantum chip according to claim 1, wherein the CPW-SIR unit is specifically a Coplanar Waveguide-2-Step Step Impedance Resonator unit.

3. The superconducting quantum chip according to claim 1, wherein the CPW-SIR unit is specifically a Coplanar Waveguide-3-Step Step Impedance Resonator unit.

4. The superconducting quantum chip according to claim 1, wherein the bit capacitor unit is specifically a bit capacitor unit of a cross structure.

5. The superconducting quantum chip according to claim 4, wherein the readout line unit is specifically a transmission line of a coplanar waveguide structure.

6. The superconducting quantum chip according to claim 5, wherein the CPW-SIR unit is specifically a λ_{g}/4 type CPW-SIR unit, and λ_{g} is a waveguide wavelength corresponding to a resonant frequency of the CPW-SIR unit.

7. A parameter determination method of a superconducting quantum chip, applied to the superconducting quantum chip according to claim 1, comprising:
determining characteristic impedance of a transmission line of each step of a Coplanar Waveguide-Step Impedance Resonator (CPW-SIR) unit according to a preset accuracy, and taking the characteristic impedance as a characteristic impedance parameter;
calculating characteristic impedance ratios among the characteristic impedances of all characteristic lines;
determining a curve relationship between an electrical length of the characteristic line and a total electrical length at the characteristic impedance ratio, and the total electrical length is specifically a sum of the electrical lengths of all the characteristic lines;
determining a minimum total electrical length interval of the total electrical length and an electrical length interval of the characteristic lines corresponding to the minimum total electrical length interval according to the curve relationship; and
determining the electrical length corresponding to the preset accuracy within the electrical length interval of the characteristic line of each step, so as to take the electrical length as an electrical length parameter of the transmission line of each step of the CPW-SIR unit.

8. The parameter determination method according to claim 7, wherein the CPW-SIR unit is a Coplanar Waveguide-2-Step Step Impedance Resonator unit; and
the process of calculating characteristic impedance ratios among the characteristic impedances of all characteristic lines comprises:
calculating a characteristic impedance ratio between the characteristic impedance of the characteristic line of a second step and the characteristic impedance of the characteristic line of a first step.

9. The parameter determination method according to claim 8, wherein the process of determining a curve relationship between an electrical length of the characteristic line and a total electrical length at the characteristic impedance ratio comprises:
determining a curve relationship between the characteristic line of the first step and the total electrical length at the characteristic impedance ratio.

10. The parameter determination method according to claim 9, wherein the process of determining the electrical length corresponding to the preset accuracy within the electrical length interval of the characteristic line of each step comprises:
determining the electrical length corresponding to the preset accuracy within the electrical length interval of the characteristic line of the first step and taking the electrical length as a first-step electrical length parameter of the characteristic line of the first step;
determining the total electrical length corresponding to the first-step electrical length parameter according to the curve relationship; and
determining a second-step electrical length parameter of the characteristic line of the second step according to the total electrical length and the first-step electrical length parameter.
